(19) United States
(12) Patent Application Publication
(10) Pub. No.: US 2024/0363482 A1
(43) Pub. Date: Oct. 31, 2024

(54) CERAMIC METAL COMPOSITE SUBSTRATE

(71) Applicant: TONG HSING ELECTRONIC INDUSTRIES, LTD., Taipei City (TW)

(72) Inventors: KAI-MOU CHOU, Taipei City (TW); SHIH-HAN WU, Taipei City (TW); JHIH-WEI LAI, Taipei City (TW); JIAN-YU SHIH, Taipei City (TW)

(21) Appl. No.: 18/755,319

(22) Filed: Jun. 26, 2024

Related U.S. Application Data
(63) Continuation-in-part of application No. 18/210,165, filed on Jun. 15, 2023.

(30) Foreign Application Priority Data
Apr. 27, 2023 (TW) 112115650
Apr. 18, 2024 (TW) 113114397

(51) Int. Cl. H01L 23/373; B32B 9/00; F28F 21/08

(52) U.S. Cl. CPC H01L 23/3735; B32B 9/005; F28F 21/081; B32B 2307/302; B32B 2307/7376

(57) ABSTRACT

A ceramic metal composite substrate includes a metal core layer, two soldering layers, and two ceramic covering layers. The metal core layer is a metal-diamond composite layer, and the metal core layer has two metallic surfaces spaced apart from each other along a thickness direction by a predetermined thickness. The two soldering layers are respectively formed on the two metallic surfaces. The two ceramic covering layers are respectively fixed to the two metallic surfaces through the two soldering layers. Each of the two ceramic covering layers has a heat-transfer coefficient greater than or equal to 20 W/m·k, and a sum of thicknesses of the two ceramic covering layers and thicknesses of the two soldering layers is less than or equal to the predetermined thickness. Each of the two ceramic covering layers overlaps at least 80% of an area of the corresponding metallic surface along the thickness direction.

### CROSS-REFERENCE TO RELATED PATENT APPLICATION

This application is a continuation-in-part of U.S. patent application Ser. No. 18/210,165 field on Jun. 15, 2023 and entitled “CERAMIC METAL COMPOSITE SUBSTRATE”, now pending. The entirety of the above-mentioned patent application is hereby incorporated by reference herein and made as a part of this specification.

This application claims the benefit of priorities to Taiwan Patent Application No. 112115650, filed on Apr. 27, 2023, and No. 113114397, filed on Apr. 18, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a ceramic substrate, and more particularly to a ceramic metal composite substrate (CMCS).

### BACKGROUND OF THE DISCLOSURE

In order to satisfy heat-dissipation requirements of a chip, a conventional substrate cooperated with the chip is usually a ceramic substrate or a metal core printed circuit board (MCPCB). However, the conventional substrate has reached its limit in terms of thermal conductivity due to such configurations, so that higher heat-dissipation requirements are difficult to be met by the conventional substrate.

### SUMMARY OF THE DISCLOSURE

In response to the above-referenced technical inadequacies, the present disclosure provides a ceramic metal composite substrate (CMCS) for effectively improving on the issues associated with conventional substrates.

In order to solve the above-mentioned problems, one of the technical aspects adopted by the present disclosure is to provide a ceramic metal composite substrate, which is a metal-diamond composite layer. The metal core layer has two metallic surfaces spaced apart from each other along a thickness direction by a predetermined thickness. The metal core layer is made of a material including copper. The two soldering layers are respectively formed on the two metallic surfaces of the metal core layer. The two ceramic covering layers are fixed to the metal core layer through the two soldering layers, respectively. Each of the two ceramic covering layers has a heat-transfer coefficient being greater than or equal to 20 W/m·k, and a sum of thicknesses of the two ceramic covering layers and thicknesses of the two soldering layers is less than or equal to the predetermined thickness. Each of the two ceramic covering layers overlaps at least 80% of an area of the corresponding metallic surface along the thickness direction.

In order to solve the above-mentioned problems, another one of the technical aspects adopted by the present disclosure is to provide a ceramic metal composite substrate, which is a metal-diamond composite layer. The metal core layer has two metallic surfaces spaced apart from each other along a thickness direction by a predetermined thickness. The metal core layer is made of a material including copper. The two ceramic covering layers are respectively formed on the two metallic surfaces of the metal core layer. Each of the two ceramic covering layers and the corresponding metallic surface jointly form a eutectic-bonding layer therebetween. Moreover, a sum of thicknesses of the two ceramic covering layers is less than or equal to the predetermined thickness, and each of the two ceramic covering layers includes a first ceramic sublayer and a second ceramic sublayer. The first ceramic sublayer is fixed onto the corresponding metallic surface through the corresponding eutectic-bonding layer. The second ceramic sublayer is formed on the first ceramic sublayer, and the second ceramic sublayer has a heat-transfer coefficient being greater than or equal to 20 W/m·k. Each of the two ceramic covering layers overlaps at least 80% of an area of the corresponding metallic surface along the thickness direction.

In order to solve the above-mentioned problems, yet another one of the technical aspects adopted by the present disclosure is to provide a ceramic metal composite substrate, which is a metal-diamond composite layer. The metal core layer has two metallic surfaces spaced apart from each other along a thickness direction by a predetermined thickness. The metal core layer is made of a material including copper. The two ceramic covering layers are respectively formed on the two metallic surfaces of the metal core layer. Each of the two ceramic covering layers and the corresponding metallic surface jointly form a diffusion-bonding interface therebetween that has a thickness of less than or equal to 1 μm. Each of the two ceramic covering layers has a heat-transfer coefficient being greater than or equal to 20 W/m·k, and a sum of thicknesses of the two ceramic covering layers is less than or equal to the predetermined thickness. Each of the two ceramic covering layers overlaps at least 80% of an area of the corresponding metallic surface along the thickness direction.

Therefore, the ceramic metal composite substrate (CMCS) of the present disclosure is provided with a specific multi-layer configuration (e.g., the two opposite sides of the metal core layer being respectively provided with the two ceramic covering layers) different from the conventional configuration, so that under the premise that the CMCS has a high reliability and a high structural strength, the performance of heat-conduction and heat-dissipation of the CMCS can be effectively increased for meeting higher heat-dissipation requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a ceramic metal composite substrate (CMCS) according to a first embodiment of the present disclosure;

FIG. 2 is a schematic cross-sectional view of the CMCS according to a second embodiment of the present disclosure;

FIG. 3 is a schematic cross-sectional view of the CMCS according to a third embodiment of the present disclosure;

FIG. 4 is a schematic cross-sectional view of the CMCS in another configuration according to the third embodiment of the present disclosure;

FIG. 5 is a schematic cross-sectional view of the CMCS according to a fourth embodiment of the present disclosure;

FIG. 6 is a schematic cross-sectional view of the CMCS according to a fifth embodiment of the present disclosure;

FIG. 7 is a schematic cross-sectional view of the CMCS according to a sixth embodiment of the present disclosure;

FIG. 8 is a schematic cross-sectional view of the CMCS in another configuration according to the sixth embodiment of the present disclosure;

FIG. 9 is a schematic cross-sectional view of the CMCS according to a seventh embodiment of the present disclosure;

FIG. 10 is a schematic cross-sectional view of the CMCS according to an eighth embodiment of the present disclosure;

FIG. 11 is a schematic cross-sectional view of the CMCS according to a ninth embodiment of the present disclosure; and

FIG. 12 is a schematic cross-sectional view of the CMCS in another configuration according to the ninth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

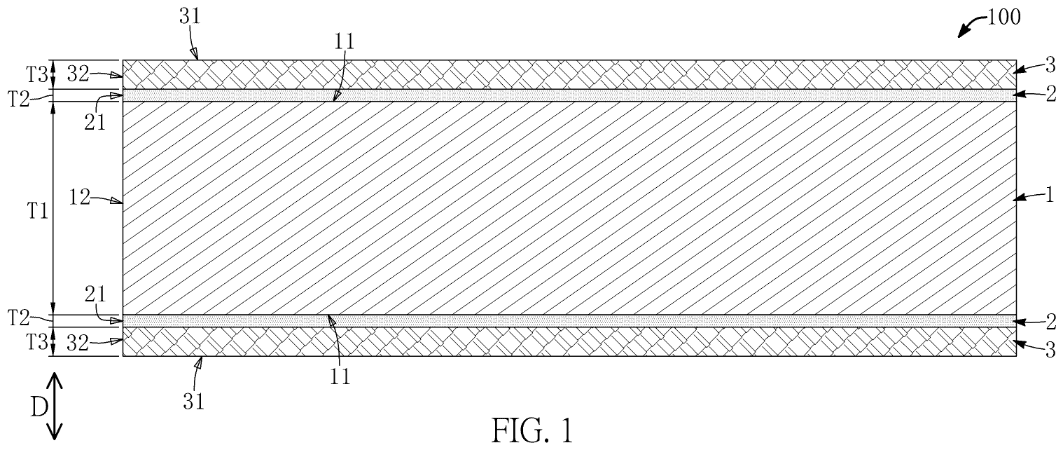

Referring to FIG. 1, a first embodiment of the present disclosure provides a ceramic metal composite substrate (CMCS) 100, which includes a metal core layer 1, two soldering layers 2 respectively formed on two opposite sides of the metal core layers 1, and two ceramic covering layers 3 that are respectively formed on the two soldering layers 2. In other words, the metal core layer 1 and any one of the two ceramic covering layers 3 are provided with one of the two soldering layers 2 sandwiched therebetween. It should be noted that any composite substrate, which includes a metal layer and a single ceramic sublayer formed on only one side of the metal layer, is different from the CMCS 100 provided by the present embodiment.

The metal core layer 1 is made of a material including at least one of copper, silver, and aluminum, and the metal core layer 1 is provided for heat-conduction. The metal core layer 1 in the present embodiment can be a copper layer, a copper-tungsten alloy layer, a metal-diamond composite layer, or a copper-molybdenum alloy layer, but the present disclosure is not limited thereto. Specifically, the copper layer can be a high-purity oxygen-free copper foil, and a percentage of copper in the copper-tungsten alloy layer or in the copper-molybdenum alloy layer can be adjusted according to design requirements, but the present disclosure is not limited thereto.

It should be noted that, the metal-diamond composite layer in the present embodiment is a composite material formed by a plurality of diamond particles provided as an aggregate and at least one of copper, silver, and aluminum that is mixed in the diamond particles. For example, the metal-diamond composite layer is a copper-diamond composite layer, a copper-aluminum-diamond composite layer, an aluminum-diamond composite layer, a copper-silver-diamond composite layer, a silver-diamond composite layer, or an aluminum-silver-diamond composite layer, but the present disclosure is not limited thereto. Specifically, since the molten copper cannot wet the diamond particles, the molten copper must penetrate and fill in the gaps between the diamond particles under ultra-high pressure to form the copper-diamond composite layer. Furthermore, aluminum can barely wet the diamond particles, so that the aluminum-diamond composite layer can be made at low pressure. In addition, the surface of the metal-diamond composite layer is preferably made of metal so as to facilitate subsequent processing and smoothing.

Moreover, the metal core layer 1 has two metallic surfaces 11 spaced apart from each other along a thickness direction D by a predetermined thickness T1. In the present embodiment, the two metallic surfaces 11 are flat surfaces and are substantially parallel to each other, and the predetermined thickness T1 can be at least 50 μm (e.g., the predetermined thickness T1 can be within a range from 300 μm to 1000 μm).

The two soldering layers 2 are respectively formed on the two metallic surfaces 11 of the metal core layer 1, and each of the two soldering layers 2 can be a brazing paste or a glass paste according to design requirements. In the present embodiment, any one of the two soldering layers 2 is preferably stacked on (or bonded to) an entirety of the corresponding metallic surface 11 and has a uniform thickness that is preferably less than or equal to 30 μm, but the present disclosure is not limited thereto.

The two ceramic covering layers 3 are fixed to the metal core layer 1 through the two soldering layers 2, respectively, and each of the two ceramic covering layers 3 has a heat-transfer coefficient being greater than or equal to 20 W/m·k. In the present embodiment, each of the two ceramic covering layers 3 is an aluminum nitride (AlN) layer that is sintered to the metal core layer 1 through the corresponding soldering layer 2, but the present disclosure is not limited thereto. For example, in other embodiments of the present disclosure not shown in the drawings, any one of the two ceramic covering layers 3 can be a silicon nitride (Si₃N₄) layer or an aluminum oxide (Al₂O₃) layer.

Specifically, each of the two soldering layers 2 is entirely arranged between the metal core layer 1 and the corresponding ceramic covering layer 3, a thickness T3 of any one of the two ceramic covering layers 3 is greater than or equal to the thickness T2 of the corresponding soldering layer 2 (e.g., the thickness T3 of each of the two ceramic covering layers 3 can be within a range from 5 μm to 350 μm), and a sum of the thicknesses T3 of the two ceramic covering layers 3 and the thicknesses T2 of the two soldering layers 2 is less than or equal to the predetermined thickness T1.

In addition, each of the two ceramic covering layers 3 has a grinding plane 31 that is arranged away from the metal core layer 1 and that is preferably parallel to any one of the two metallic surfaces 11. Accordingly, a flatness and a thickness of the CMCS 100 in the present embodiment can be precisely controlled by grinding the two ceramic covering layers 3.

In other words, each of the two ceramic covering layers 3 overlaps (or covers) at least 80% of an area of the corresponding metallic surface 11 along the thickness direction D. In the present embodiment, outer lateral sides 12 of the metal core layer 1, outer lateral sides 21 of the two soldering layers 2, and outer lateral sides 32 of the two ceramic covering layers 3 are flush (or coplanar) with each other along the thickness direction D. In other words, a part of the metal core layer 1 exposed in an external environment only includes the outer lateral sides 12. Moreover, compared to the metal core layer 1, any one of the two ceramic covering layers 3 and the corresponding soldering layer 2 connected thereto are mirror-symmetrical to another one of the two ceramic covering layers 3 and the corresponding soldering layer 2 connected thereto, but the present disclosure is not limited thereto.

In summary, the CMCS 100 of the present embodiment is provided with a specific multi-layer configuration (e.g., the two opposite sides of the metal core layer 1 being respectively provided with the two ceramic covering layers 3) different from the conventional configuration, so that under the premise that the CMCS 100 has a high reliability and a high structural strength, the performance of heat-conduction and heat-dissipation of the CMCS 100 can be effectively increased for meeting higher heat-dissipation requirements.

It should be noted that the CMCS 100 provided by the present embodiment is limited to having the specific multi-layer configuration. In other words, according to design requirements, the CMCS 100 provided by the present embodiment can be regarded as consisting of the metal core layer 1, the two soldering layers 2 respectively formed on the two opposite sides of the metal core layer 1, and the two ceramic covering layers 3 that are respectively formed on the two soldering layers 2, but the present disclosure is not limited thereto.

### Second Embodiment

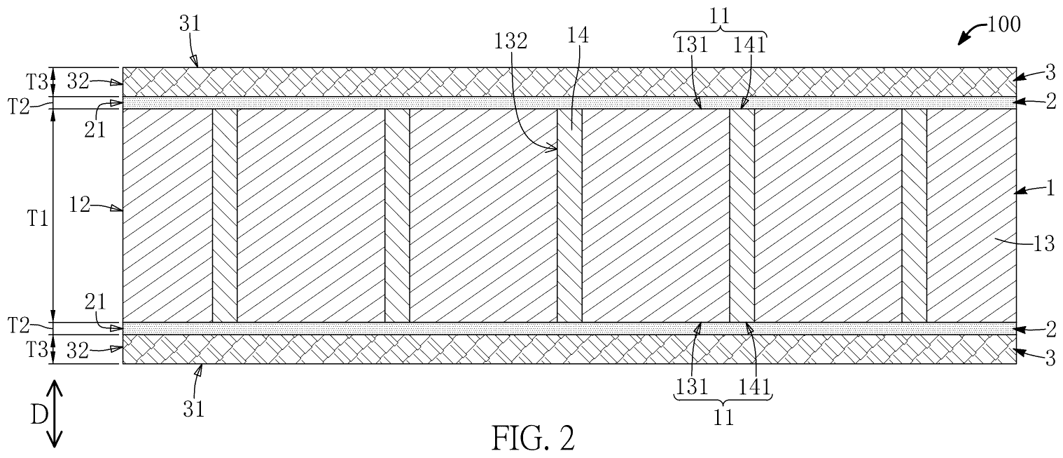

Referring to FIG. 2, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the metal core layer 1 includes a copper layer 13 and an embedded metal 14 that is embedded in the copper layer 13. The embedded metal 14 can be made of tungsten, molybdenum, copper-tungsten alloy, or copper-molybdenum alloy. The copper layer 13 has at least one filling hole 132 formed in a surface 131 thereof. The embedded metal 13 is filled in an entirety of the at least one filling hole 132, and at least one of two ends 141 of the embedded metal 14 is flush with the surface 131 of the copper layer 13 and is gaplessly connected to at least one of the two soldering layers 2.

Specifically, the at least one filling hole 132 penetrates through the copper layer 13 along the thickness direction D, and the two ends 141 of the embedded metal 14 are gaplessly connected to the two soldering layers 2, respectively, but the present disclosure is not limited thereto. For example, in other embodiments of the present disclosure not shown in the drawings, the at least one filling hole 132 can be a blind hole that does not penetrate through the copper layer 13.

### Third Embodiment

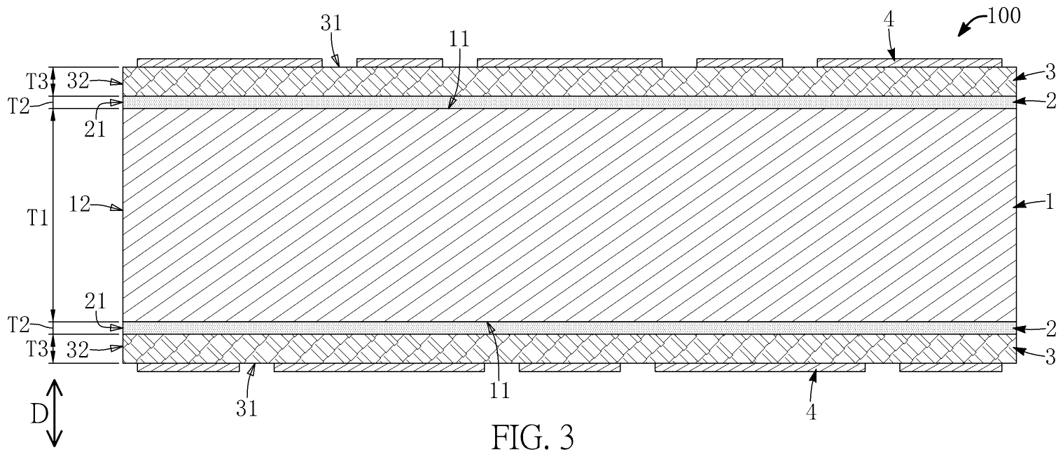

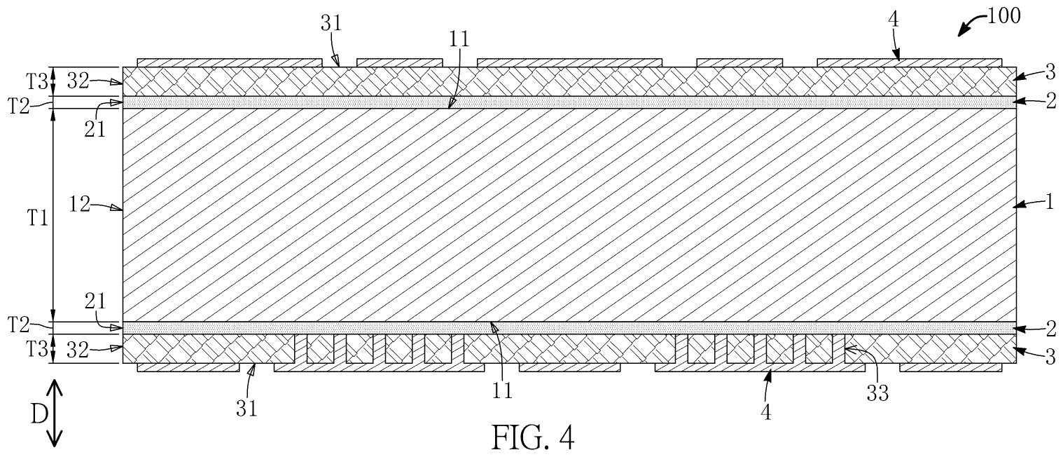

Referring to FIG. 3 and FIG. 4, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the ceramic metal composite substrate (CMCS) 100 further includes two circuit layers 4 respectively formed on the grinding planes 31 of the two ceramic covering layers 3 in a direct plated copper (DPC) forming manner. Any one of the two circuit layers 4 in the present embodiment can be defined as a DPC circuit layer. Specifically, the grinding planes 31 have a good degree of flatness by grinding the two ceramic covering layers 3, thereby facilitating formation of the two circuit layers 4, but the present disclosure is not limited thereto.

In addition, in order to increase performance of heat-conduction or heat-dissipation of the circuit layer 4, at least one of the two ceramic covering layers 3 has a thru-hole 33 that is recessed (along the thickness direction D) from the grinding plane 31 thereof to the corresponding soldering layer 2, and a corresponding one of the two circuit layers 4 is filled in an entirety of the thru-hole 33 so as to be connected to the corresponding soldering layer 2. Moreover, the two circuit layers 4 can be respectively formed on the grinding planes 31 of the two ceramic covering layers 3 in a thin film metallized substrate forming manner (e.g., sputtered titanium and platinum, or evaporated titanium and platinum). In other words, the forming manner of any one of the two circuit layers 4 can be at least one of the DPC forming manner or the thin film metallized substrate forming manner.

It should be noted that the CMCS 100 provided by the present embodiment is limited to having the specific multi-layer configuration. In other words, according to design requirements, the CMCS 100 provided by the present embodiment can be regarded as consisting of the metal core layer 1, the two soldering layers 2 respectively formed on the two opposite sides of the metal core layer 1, the two ceramic covering layers 3 respectively formed on the two soldering layers 2, and the two circuit layers 4 that are respectively formed on the two ceramic covering layers 3, but the present disclosure is not limited thereto.

### Fourth Embodiment

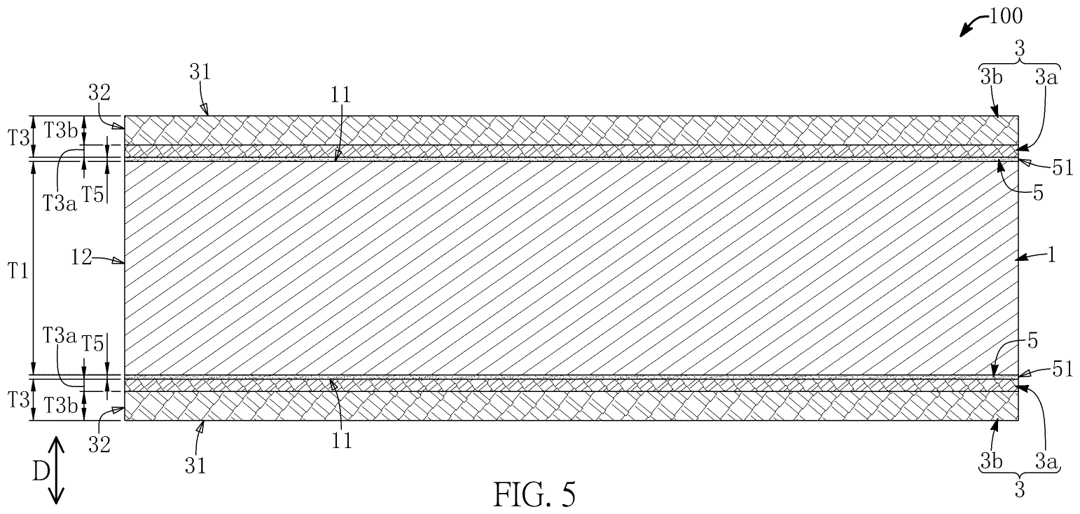

Referring to FIG. 5, a fourth embodiment of the present disclosure provides a ceramic metal composite substrate (CMCS) 100, which includes a metal core layer 1 and two ceramic covering layers 3 that are respectively formed on two opposite sides of the metal core layers 1. It should be noted that any composite substrate including a metal layer and a single ceramic sublayer that is only formed on one side of the metal layer, is different from the CMCS 100 provided by the present embodiment.

The metal core layer 1 is made of a material including at least one of copper, silver, and aluminum, and the metal core layer 1 is provided for heat-conduction. The metal core layer 1 in the present embodiment can be a copper layer, a copper-tungsten alloy layer, a metal-diamond composite layer, or a copper-molybdenum alloy layer, but the present disclosure is not limited thereto. Specifically, the copper layer can be a high-purity oxygen-free copper foil, and the percentage of copper in the copper-tungsten alloy layer or the copper-molybdenum alloy layer can be adjusted according to design requirements, but the present disclosure is not limited thereto.

It should be noted that, the metal-diamond composite layer in the present embodiment is a composite material formed by a plurality of diamond particles provided as an aggregate and at least one of copper, silver, and aluminum that is mixed in the diamond particles. For example, the metal-diamond composite layer is a copper-diamond composite layer, a copper-aluminum-diamond composite layer, an aluminum-diamond composite layer, a copper-silver-diamond composite layer, a silver-diamond composite layer, or an aluminum-silver-diamond composite layer, but the present disclosure is not limited thereto. Specifically, since the molten copper cannot wet the diamond particles, the molten copper must penetrate and fill in the gaps between the diamond particles under ultra-high pressure to form the copper-diamond composite layer. Furthermore, aluminum can barely wet the diamond particles, so that the aluminum-diamond composite layer can be made at low pressure. In addition, the surface of the metal-diamond composite layer is preferably made of metal so as to facilitate subsequent processing and smoothing.

Moreover, the metal core layer 1 has two metallic surfaces 11 spaced apart from each other along a thickness direction D by a predetermined thickness T1. In the present embodiment, the two metallic surfaces 11 are flat surfaces and are substantially parallel to each other, and the predetermined thickness T1 can be at least 50 μm (e.g., the predetermined thickness T1 can be within a range from 300 μm to 1000 μm).

The two ceramic covering layers 3 are respectively formed on the two metallic surfaces 11 of the metal core layer 1. Each of the two ceramic covering layers 3 and the corresponding metallic surface 11 jointly form a eutectic-bonding layer 5 therebetween. In the present embodiment, each of the two the two ceramic covering layers 3 is eutectic-bonded to the metal core layer 1 in a direct bonded copper (DBC) forming manner, and a thickness T5 of any one of the two eutectic-bonding layers 5 is preferably less than or equal to 3 μm.

Specifically, each of the two ceramic covering layers 3 includes a first ceramic sublayer 3a and a second ceramic sublayer 3b that is formed on the first ceramic sublayer 3a. In each of the two ceramic covering layers 3, the first ceramic sublayer 3a is fixed onto the corresponding metallic surface 11 through the corresponding eutectic-bonding layer 5 (e.g., the first ceramic sublayer 3a is an aluminum oxide layer having a thickness T3a within a range from 5 μm to 15 μm), and the second ceramic sublayer 3b has a heat-transfer coefficient being greater than or equal to 20 W/m·k (e.g., the second ceramic sublayer 3b is an aluminum nitride layer having a thickness T3b within a range from 5 μm to 350 μm), but the present disclosure is not limited thereto. For example, in other embodiments of the present disclosure not shown in the drawings, the second ceramic sublayer 3b can be a silicon nitride layer.

Specifically, the thickness T3b of the second ceramic sublayer 3b of any one of the two ceramic covering layers 3 is greater than or equal to the thickness T3a of the corresponding first ceramic sublayer 3a connected thereto, and a sum of thicknesses T3 of the two ceramic covering layers 3 is less than or equal to the predetermined thickness T1. In addition, the second ceramic sublayer 3b of each of the two ceramic covering layers 3 has a grinding plane 31 that is arranged away from the metal core layer 1 and that is preferably parallel to any one of the two metallic surfaces 11. Accordingly, a flatness and a thickness of the CMCS 100 in the present embodiment can be precisely controlled by grinding the two the second ceramic sublayers 3b.

In other words, each of the two ceramic covering layers 3 overlaps (or covers) at least 80% of an area of the corresponding metallic surface 11 along the thickness direction D. In the present embodiment, outer lateral sides 12 of the metal core layer 1, outer lateral sides 51 of the two eutectic-bonding layers 5, and outer lateral sides 32 of the two ceramic covering layers 3 are flush (or coplanar) with each other along the thickness direction D. In other words, a part of the metal core layer 1 exposed in an external environment only includes the outer lateral sides 12. Moreover, compared to the metal core layer 1, any one of the two ceramic covering layers 3 and the corresponding eutectic-bonding layer 5 connected thereto are mirror-symmetrical to another one of the two ceramic covering layers 3 and the corresponding eutectic-bonding layer 5 connected thereto, but the present disclosure is not limited thereto.

In summary, the CMCS 100 of the present embodiment is provided with a specific multi-layer configuration (e.g., the two opposite sides of the metal core layer 1 being respectively provided with the two ceramic covering layers 3) different from the conventional configuration, so that under the premise that the CMCS 100 has a high reliability and a high structural strength, the performance of heat-conduction and heat-dissipation of the CMCS 100 can be effectively increased for meeting higher heat-dissipation requirements.

It should be noted that the CMCS 100 provided by the present embodiment is limited to having the specific multi-layer configuration. In other words, according to design requirements, the CMCS 100 provided by the present embodiment can be regarded as consisting of the metal core layer 1, the two ceramic covering layers 3 respectively formed on the two opposite sides of the metal core layer 1, and the two eutectic-bonding layers 5 that are formed by the eutectic interaction between the metal core layer 1 and each of the two ceramic covering layers 3, but the present disclosure is not limited thereto.

### Fifth Embodiment

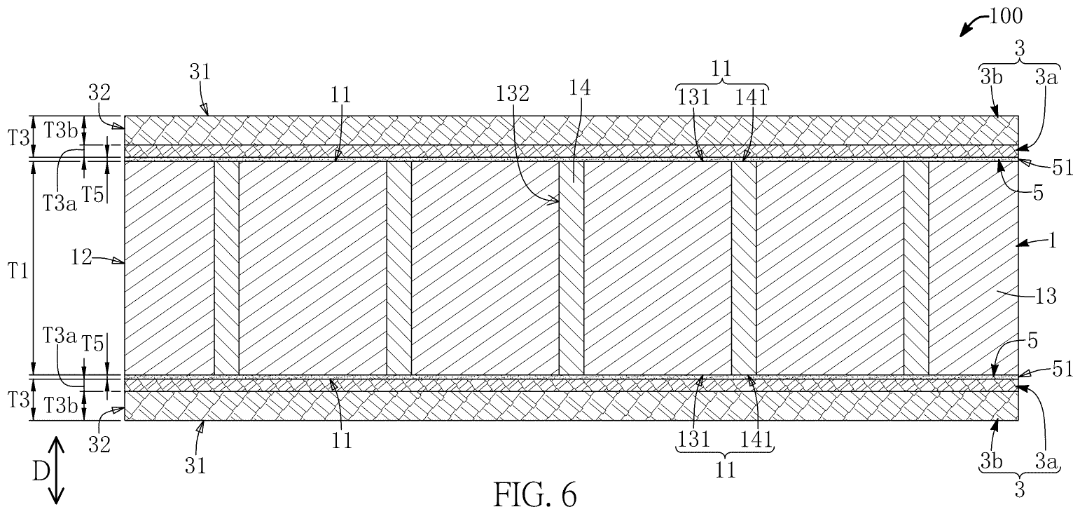

Referring to FIG. 6, a fifth embodiment of the present disclosure, which is similar to the fourth embodiment of the present disclosure, is provided. For the sake of brevity, descriptions of the same components in the fourth and fifth embodiments of the present disclosure will be omitted herein, and the following description only discloses different features between the fourth and fifth embodiments.

In the present embodiment, the metal core layer 1 includes a copper layer 13 and an embedded metal 14 that is embedded in the copper layer 13. The embedded metal 14 can be made of tungsten, molybdenum, copper-tungsten alloy, or copper-molybdenum alloy. The copper layer 13 has at least one filling hole 132 formed in a surface 131 thereof. The embedded metal 13 is filled to occupy an entirety of the at least one filling hole 132, and at least one of two ends 141 of the embedded metal 14 is flush with the surface 131 of the copper layer 13 and is gaplessly connected to at least one of the two eutectic-bonding layers 5.

Specifically, the at least one filling hole 132 penetrates through the copper layer 13 along the thickness direction D, and the two ends 141 of the embedded metal 14 are gaplessly connected to the two eutectic-bonding layers 5, respectively, but the present disclosure is not limited thereto. For example, in other embodiments of the present disclosure not shown in the drawings, the at least one filling hole 132 can be a blind hole that does not penetrate through the copper layer 13.

### Sixth Embodiment

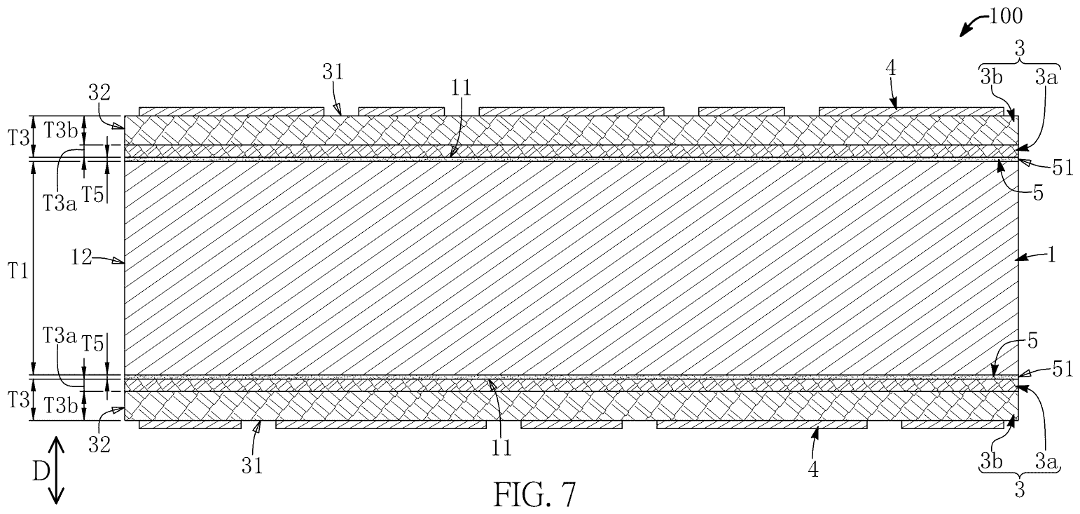

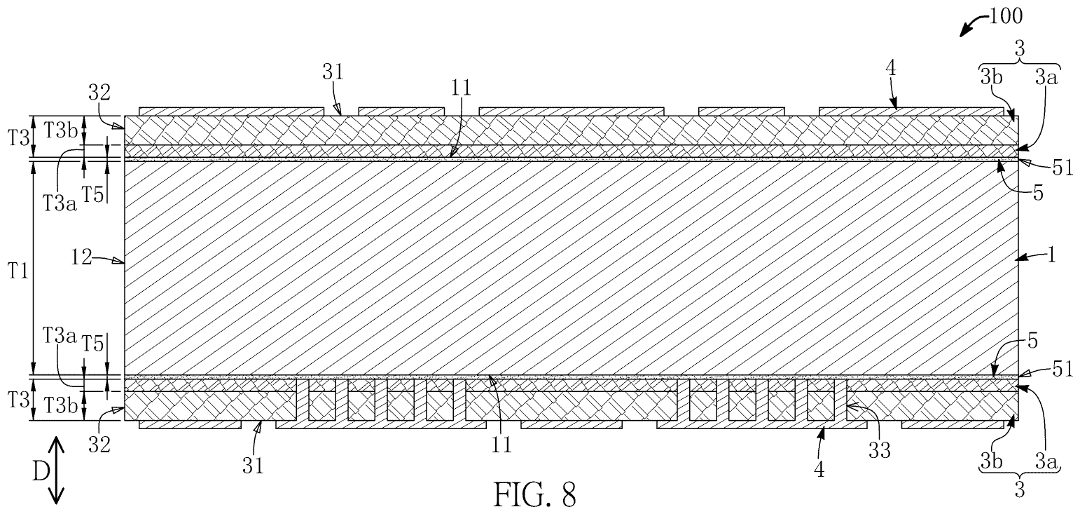

Referring to FIG. 7 and FIG. 8, a sixth embodiment of the present disclosure, which is similar to the fourth embodiment of the present disclosure, is provided. For the sake of brevity, descriptions of the same components in the fourth and sixth embodiments of the present disclosure will be omitted herein, and the following description only discloses different features between the fourth and sixth embodiments.

In the present embodiment, the ceramic metal composite substrate (CMCS) 100 further includes two circuit layers 4 respectively formed on the grinding planes 31 of the two ceramic covering layers 3 in a direct plated copper (DPC) forming manner. Any one of the two circuit layers 4 in the present embodiment can be defined as a DPC circuit layer. Specifically, the grinding planes 31 have a good degree of flatness by grinding the two ceramic covering layers 3, thereby facilitating formation of the two circuit layers 4, but the present disclosure is not limited thereto.

In addition, in order to increase performance of heat-conduction or heat-dissipation of the circuit layer 4, at least one of the two ceramic covering layers 3 has a thru-hole 33 that is recessed (along the thickness direction D) from the grinding plane 31 thereof to the corresponding eutectic-bonding layer 5, and a corresponding one of the two circuit layers 4 is filled in an entirety of the thru-hole 33 so as to be connected to the corresponding eutectic-bonding layer 5. Moreover, the two circuit layers 4 can be respectively formed on the grinding planes 31 of the two ceramic covering layers 3 in a thin film metallized substrate forming manner (e.g., sputtered titanium and platinum, or evaporated titanium and platinum). In other words, the forming manner of any one of the two circuit layers 4 can be at least one of the DPC forming manner or the thin film metallized substrate forming manner.

It should be noted that the CMCS 100 provided by the present embodiment is limited to having the specific multi-layer configuration. In other words, according to design requirements, the CMCS 100 provided by the present embodiment can be regarded as consisting of the metal core layer 1, the two ceramic covering layers 3 respectively formed on the two opposite sides of the metal core layer 1, the two eutectic-bonding layers 5 formed by the eutectic interaction between the metal core layer 1 and each of the two ceramic covering layers 3, and the two circuit layers 4 that are respectively formed on the two ceramic covering layers 3, but the present disclosure is not limited thereto.

### Seventh Embodiment

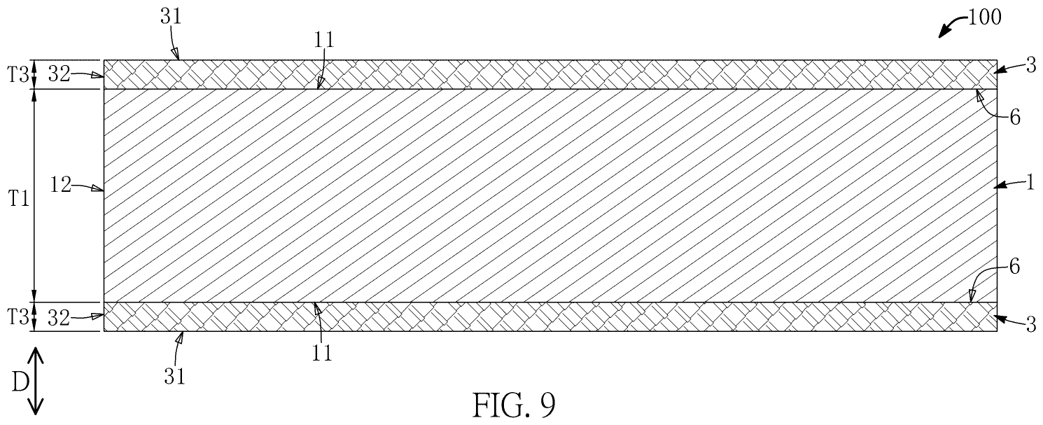

Referring to FIG. 9, a seventh embodiment of the present disclosure provides a ceramic metal composite substrate (CMCS) 100, which includes a metal core layer 1 and two ceramic covering layers 3 that are respectively formed on the two soldering layers 2. It should be noted that any composite substrate, which includes a metal layer and a single ceramic sublayer only formed on one side of the metal layer, is different from the CMCS 100 provided by the present embodiment.

The metal core layer 1 is made of a material including at least one of copper, silver, and aluminum, and the metal core layer 1 is provided for heat-conduction. The metal core layer 1 in the present embodiment can be a copper layer, a copper-tungsten alloy layer, a metal-diamond composite layer, or a copper-molybdenum alloy layer, but the present disclosure is not limited thereto. Specifically, the copper layer can be a high-purity oxygen-free copper foil, and the percentage of copper in the copper-tungsten alloy layer or the copper-molybdenum alloy layer can be adjusted according to design requirements, but the present disclosure is not limited thereto.

It should be noted that, the metal-diamond composite layer in the present embodiment is a composite material formed by a plurality of diamond particles provided as an aggregate and at least one of copper, silver, and aluminum that is mixed in the diamond particles. For example, the metal-diamond composite layer is a copper-diamond composite layer, a copper-aluminum-diamond composite layer, an aluminum-diamond composite layer, a copper-silver-diamond composite layer, a silver-diamond composite layer, or an aluminum-silver-diamond composite layer, but the present disclosure is not limited thereto. Specifically, since the molten copper cannot wet the diamond particles, the molten copper must penetrate and fill in the gaps between the diamond particles under ultra-high pressure to form the copper-diamond composite layer. Furthermore, aluminum can barely wet the diamond particles, so that the aluminum-diamond composite layer can be made at low pressure. In addition, the surface of the metal-diamond composite layer is preferably made of metal so as to facilitate subsequent processing and smoothing.

Moreover, the metal core layer 1 has two metallic surfaces 11 spaced apart from each other along a thickness direction D by a predetermined thickness T1. In the present embodiment, the two metallic surfaces 11 are flat surfaces and are substantially parallel to each other, and the predetermined thickness T1 can be at least 50 μm (e.g., the predetermined thickness T1 can be within a range from 300 μm to 1000 μm).

The two soldering layers 2 are respectively formed on the two metallic surfaces 11 of the metal core layer 1. Each of the two ceramic covering layers 3 and the corresponding metallic surface 11 jointly form a diffusion-bonding interface 6 therebetween that has a thickness of less than or equal to 1 μm. In other words, each of the two metallic surfaces 11 is formed with the diffusion-bonding interface 6 arranged thereon. Each of the two ceramic covering layers 3 has a heat-transfer coefficient being greater than or equal to 20 W/m·k. In the present embodiment, each of the two ceramic covering layers 3 is an aluminum nitride (AlN) layer, but the present disclosure is not limited thereto. For example, in other embodiments of the present disclosure not shown in the drawings, any one of the two ceramic covering layers 3 can be a silicon nitride (Si₃N₄) layer or an aluminum oxide (Al₂O₃) layer.

Specifically, a thickness T3 of any one of the two ceramic covering layers 3 can be within a range from 5 μm to 350 μm, and a sum of the thicknesses T3 of the two ceramic covering layers 3 is less than or equal to the predetermined thickness T1. In addition, each of the two ceramic covering layers 3 has a grinding plane 31 that is arranged away from the metal core layer 1 and that is preferably parallel to any one of the two metallic surfaces 11. Accordingly, a flatness and a thickness of the CMCS 100 in the present embodiment can be precisely controlled by grinding the two ceramic covering layers 3.

In other words, each of the two ceramic covering layers 3 overlaps (or covers) at least 80% of an area of the corresponding metallic surface 11 along the thickness direction D. In the present embodiment, outer lateral sides 12 of the metal core layer 1 and outer lateral sides 32 of the two ceramic covering layers 3 are flush (or coplanar) with each other along the thickness direction D. In other words, a part of the metal core layer 1 exposed in an external environment only includes the outer lateral sides 12. Moreover, compared to the metal core layer 1, any one of the two ceramic covering layers 3 is mirror-symmetrical to another one of the two ceramic covering layers 3, but the present disclosure is not limited thereto.

In summary, the CMCS 100 of the present embodiment is provided with a specific multi-layer configuration (e.g., the two opposite sides of the metal core layer 1 being respectively provided with the two ceramic covering layers 3) different from the conventional configuration, so that under the premise that the CMCS 100 has a high reliability and a high structural strength, the performance of heat-conduction and heat-dissipation of the CMCS 100 can be effectively increased for meeting higher heat-dissipation requirements.

It should be noted that the CMCS 100 provided by the present embodiment is limited to having the specific multi-layer configuration. In other words, according to design requirements, the CMCS 100 provided by the present embodiment can be regarded as consisting of the metal core layer 1 and the two ceramic covering layers 3 that are respectively formed on the two opposite sides of the metal core layer 1, but the present disclosure is not limited thereto.

### Eighth Embodiment

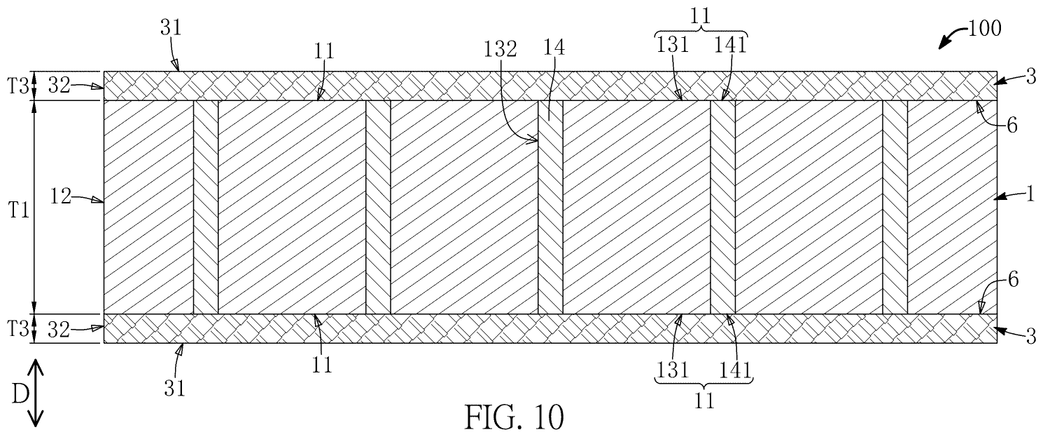

Referring to FIG. 10, an eighth embodiment of the present disclosure, which is similar to the seventh embodiment of the present disclosure, is provided. For the sake of brevity, descriptions of the same components in the seventh and eighth embodiments of the present disclosure will be omitted herein, and the following description only discloses different features between the seventh and eighth embodiments.

In the present embodiment, the metal core layer 1 includes a copper layer 13 and an embedded metal 14 that is embedded in the copper layer 13. The embedded metal 14 can be made of tungsten, molybdenum, copper-tungsten alloy, or copper-molybdenum alloy. The copper layer 13 has at least one filling hole 132 formed in a surface 131 thereof. The embedded metal 13 is filled in an entirety of the at least one filling hole 132, and at least one of two ends 141 of the embedded metal 14 is flush with the surface 131 of the copper layer 13 and forms at least part of the corresponding diffusion-bonding interface 6.

Specifically, the at least one filling hole 132 penetrates through the copper layer 13 along the thickness direction D, and the two ends 141 of the embedded metal 14 respectively form parts of the two diffusion-bonding interfaces 6, but the present disclosure is not limited thereto. For example, in other embodiments of the present disclosure not shown in the drawings, the at least one filling hole 132 can be a blind hole that does not penetrate through the copper layer 13.

### Ninth Embodiment

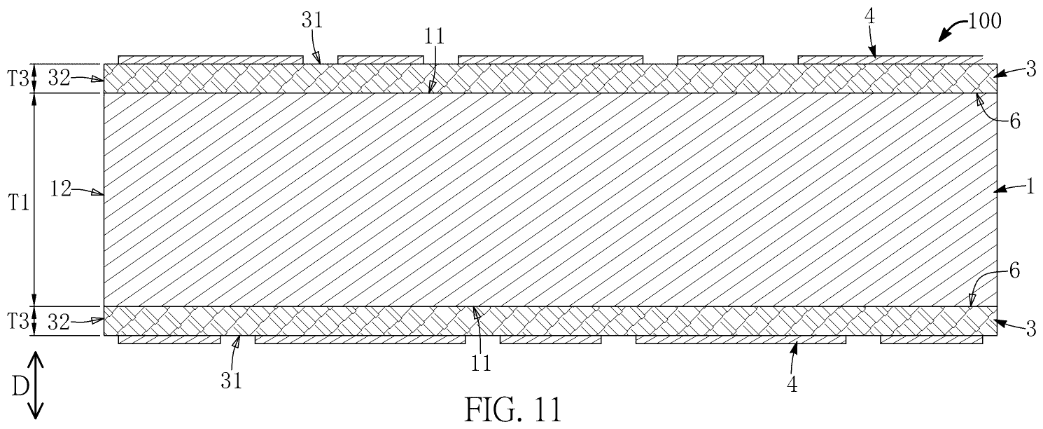

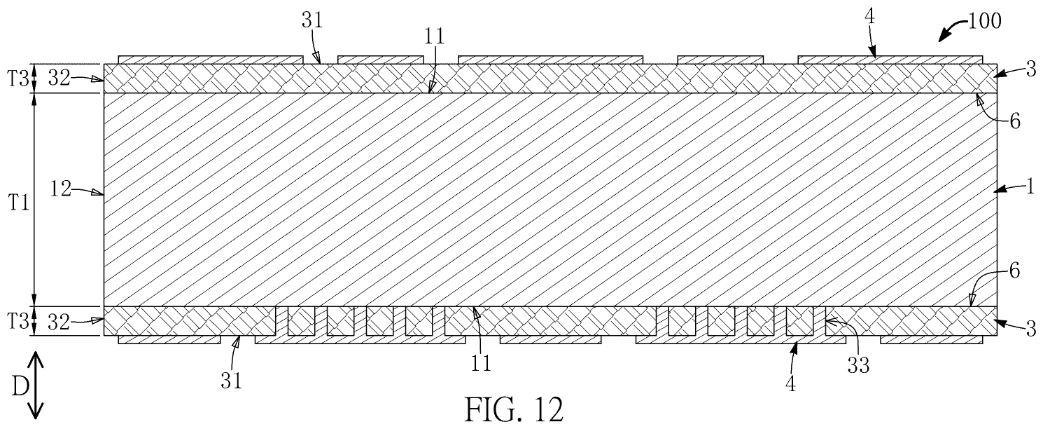

Referring to FIG. 11 and FIG. 12, a ninth embodiment of the present disclosure, which is similar to the seventh embodiment of the present disclosure, is provided. For the sake of brevity, descriptions of the same components in the seventh and ninth embodiments of the present disclosure will be omitted herein, and the following description only discloses different features between the seventh and ninth embodiments.

In the present embodiment, the ceramic metal composite substrate (CMCS) 100 further includes two circuit layers 4 respectively formed on the grinding planes 31 of the two ceramic covering layers 3 in a direct plated copper (DPC) forming manner. Any one of the two circuit layers 4 in the present embodiment can be defined as a DPC circuit layer. Specifically, the grinding planes 31 have a good degree of flatness by grinding the two ceramic covering layers 3, thereby facilitating formation of the two circuit layers 4, but the present disclosure is not limited thereto.

In addition, in order to increase performance of heat-conduction or heat-dissipation of the circuit layer 4, at least one of the two ceramic covering layers 3 has a thru-hole 33 that is recessed (along the thickness direction D) from the grinding plane 31 thereof to the corresponding diffusion-bonding interface 6, and a corresponding one of the two circuit layers 4 is filled in an entirety of the thru-hole 33 so as to be connected to the metal core layer 1. Moreover, the two circuit layers 4 can be respectively formed on the grinding planes 31 of the two ceramic covering layers 3 in a thin film metallized substrate forming manner (e.g., sputtered titanium and platinum, or evaporated titanium and platinum). In other words, the forming manner of any one of the two circuit layers 4 can be at least one of the DPC forming manner or the thin film metallized substrates forming manner.

It should be noted that the CMCS 100 provided by the present embodiment is limited to having the specific multi-layer configuration. In other words, according to design requirements, the CMCS 100 provided by the present embodiment can be regarded as consisting of the metal core layer 1, the two ceramic covering layers 3 respectively formed on the two opposite sides of the metal core layer 1, and the two circuit layers 4 that are respectively formed on the two ceramic covering layers 3, but the present disclosure is not limited thereto.

### Beneficial Effects of the Embodiments

In conclusion, the ceramic metal composite substrate (CMCS) of the present disclosure is provided with a specific multi-layer configuration (e.g., the two opposite sides of the metal core layer being respectively provided with the two ceramic covering layers) different from the conventional configuration, so that under the premise that the CMCS has a high reliability and a high structural strength, the performance of heat-conduction and heat-dissipation of the CMCS can be effectively increased for meeting higher heat-dissipation requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A ceramic metal composite substrate, comprising:
a metal core layer having two metallic surfaces spaced apart from each other along a thickness direction by a predetermined thickness, wherein the metal core layer is a metal-diamond composite layer;
two soldering layers respectively formed on the two metallic surfaces of the metal core layer; and
two ceramic covering layers fixed to the metal core layer through the two soldering layers, respectively, wherein each of the two ceramic covering layers has a heat-transfer coefficient being greater than or equal to 20 W/m·k, and a sum of thicknesses of the two ceramic covering layers and thicknesses of the two soldering layers is less than or equal to the predetermined thickness;
wherein each of the two ceramic covering layers overlaps at least 80% of an area of the corresponding metallic surface along the thickness direction.

2. The ceramic metal composite substrate according to claim 1, wherein the metal core layer is made of a material including at least one of copper, silver, and aluminum, and each of the two ceramic covering layers is an aluminum nitride (AlN) layer that is sintered to the metal core layer through the corresponding soldering layer and that has a thickness being within a range from 5 μm to 350 μm.

3. The ceramic metal composite substrate according to claim 1, wherein the metal core layer includes a plurality of diamond particles provided as an aggregate and at least one of copper, silver, and aluminum that is mixed in the diamond particles.

4. The ceramic metal composite substrate according to claim 3, wherein the metal-diamond composite layer is a copper-diamond composite layer, a copper-aluminum-diamond composite layer, an aluminum-diamond composite layer, a copper-silver-diamond composite layer, a silver-diamond composite layer, or an aluminum-silver-diamond composite layer.

5. The ceramic metal composite substrate according to claim 1, wherein each of the two soldering layers is a brazing paste or a glass paste, and a thickness of any one of the two ceramic covering layers is greater than or equal to a thickness of the corresponding soldering layer that is less than or equal to 30 μm.

6. The ceramic metal composite substrate according to claim 1, wherein each of the two ceramic covering layers has a grinding plane arranged away from the metal core layer.

7. The ceramic metal composite substrate according to claim 6, further comprising two circuit layers respectively formed on the grinding planes of the two ceramic covering layers in a direct plated copper (DPC) manner or in a thin film metallized substrate forming manner.

8. The ceramic metal composite substrate according to claim 7, wherein at least one of the two ceramic covering layers has a thru-hole that is recessed from the grinding plane thereof to the corresponding soldering layer, and a corresponding one of the two circuit layers is filled to occupy an entirety of the thru-hole so as to be connected to the corresponding soldering layer.

9. A ceramic metal composite substrate, comprising:
a metal core layer having two metallic surfaces spaced apart from each other along a thickness direction by a predetermined thickness, wherein the metal core layer is a metal-diamond composite layer; and
two ceramic covering layers respectively formed on the two metallic surfaces of the metal core layer, wherein each of the two ceramic covering layers and the corresponding metallic surface jointly form a eutectic-bonding layer therebetween, and wherein a sum of thicknesses of the two ceramic covering layers is less than or equal to the predetermined thickness, and each of the two ceramic covering layers includes:
a first ceramic sublayer fixed onto the corresponding metallic surface through the corresponding eutectic-bonding layer; and
a second ceramic sublayer formed on the first ceramic sublayer, wherein the second ceramic sublayer has a heat-transfer coefficient being greater than or equal to 20 W/m·k;
wherein each of the two ceramic covering layers overlaps at least 80% of an area of the corresponding metallic surface along the thickness direction.

10. The ceramic metal composite substrate according to claim 9, wherein the metal core layer is made of a material including at least one of copper, silver, and aluminum, and each of the two ceramic covering layers is eutectic-bonded to the metal core layer in a direct bonded copper (DBC) forming manner, and a thickness of any one of the two eutectic-bonding layers is less than or equal to 3 μm, and wherein, in each of the two ceramic covering layers, the first ceramic sublayer is an aluminum oxide (Al₂O₃) layer having a thickness within a range from 5 μm to 15 μm, and the second ceramic sublayer is an aluminum nitride (AlN) layer having a thickness within a range from 5 μm to 350 μm.

11. The ceramic metal composite substrate according to claim 9, wherein the metal core layer includes a plurality of diamond particles provided as an aggregate and at least one of copper, silver, and aluminum that is mixed in the diamond particles.

12. The ceramic metal composite substrate according to claim 11, wherein the metal-diamond composite layer is a copper-diamond composite layer, a copper-aluminum-diamond composite layer, an aluminum-diamond composite layer, a copper-silver-diamond composite layer, a silver-diamond composite layer, or an aluminum-silver-diamond composite layer.

13. The ceramic metal composite substrate according to claim 9, wherein the second ceramic sublayer of each of the two ceramic covering layers has a grinding plane arranged away from the metal core layer.

14. The ceramic metal composite substrate according to claim 13, further comprising two circuit layers respectively formed on the grinding planes of the two ceramic covering layers in a direct plated copper (DPC) forming manner or in a thin film metallized substrate forming manner.

15. The ceramic metal composite substrate according to claim 14, wherein at least one of the two ceramic covering layers has a thru-hole that is recessed from the grinding plane thereof to the corresponding eutectic-bonding layer, and a corresponding one of the two circuit layers is filled to occupy an entirety of the thru-hole so as to be connected to the corresponding eutectic-bonding layer.

16. A ceramic metal composite substrate, comprising:
a metal core layer having two metallic surfaces spaced apart from each other along a thickness direction by a predetermined thickness, wherein the metal core layer is a metal-diamond composite layer; and
two ceramic covering layers respectively formed on the two metallic surfaces of the metal core layer, wherein each of the two ceramic covering layers and the corresponding metallic surface jointly form a diffusion-bonding interface therebetween that has a thickness of less than or equal to 1 μm, and wherein each of the two ceramic covering layers has a heat-transfer coefficient being greater than or equal to 20 W/m·k, and a sum of thicknesses of the two ceramic covering layers is less than or equal to the predetermined thickness;
wherein each of the two ceramic covering layers overlaps at least 80% of an area of the corresponding metallic surface along the thickness direction.

17. The ceramic metal composite substrate according to claim 16, wherein the metal core layer is made of a material including at least one of copper, silver, and aluminum, and each of the two ceramic covering layers is an aluminum nitride (AlN) layer having a thickness within a range from 5 μm to 350 μm.

18. The ceramic metal composite substrate according to claim 16, wherein the metal core layer includes a plurality of diamond particles provided as an aggregate and at least one of copper, silver, and aluminum that is mixed in the diamond particles, and the metal-diamond composite layer is a copper-diamond composite layer, a copper-aluminum-diamond composite layer, an aluminum-diamond composite layer, a copper-silver-diamond composite layer, a silver-diamond composite layer, or an aluminum-silver-diamond composite layer.

19. The ceramic metal composite substrate according to claim 16, wherein each of the two ceramic covering layers has a grinding plane arranged away from the metal core layer, and wherein the ceramic metal composite substrate includes two circuit layers respectively formed on the grinding planes of the two ceramic covering layers in a direct plated copper (DPC) forming manner or in a thin film metallized substrate forming manner.

20. The ceramic metal composite substrate according to claim 19, wherein at least one of the two ceramic covering layers has a thru-hole that is recessed from the grinding plane thereof to the corresponding diffusion-bonding interface, and a corresponding one of the two circuit layers is filled to occupy an entirety of the thru-hole so as to be connected to the metal core layer.
